(19) United States
(12) Patent Application Publication
(10) Pub. No.: US 2021/0399214 A1
(43) Pub. Date: Dec. 23, 2021

(54) METHOD FOR MANUFACTURING MAGNETIC TUNNEL JUNCTION

(71) Applicant: JIANGSU LEUVEN INSTRUMENTS CO., LTD, Jiangsu (CN)

(72) Inventors: Dongchen CHE, Jiangsu (CN); Ziming LIU, Jiangsu (CN); Zhongyuan JIANG, Jiangsu (CN); Juebin WANG, Jiangsu (CN); Hushan CUI, Jiangsu (CN); Dongdong HU, Jiangsu (CN); Lu CHEN, Jiangsu (CN); Zhiwen ZOU, Jiangsu (CN); Hongyue SUN, Jiangsu (CN); Kaidong XU, Jiangsu (CN)

(21) Appl. No.: 17/289,511

(22) PCT Filed: May 23, 2019
(86) PCT No.: PCT/CN2019/088154

§ 371 Date: Apr. 28, 2021

(30) Foreign Application Priority Data
Nov. 2, 2018 (CN) 201811298680.4

(51) Int. Cl. H01L 43/12

(52) U.S. Cl. CPC H01L 43/12

(57) ABSTRACT

Disclosed is a method for manufacturing a magnetic tunnel junction, using an etching apparatus including a sample loading chamber, a vacuum transition chamber, a reactive ion plasma etching chamber, an ion beam etching chamber, a coating chamber and a vacuum transmission chamber, wherein a magnetic tunnel junction is etched, cleaned and coated for protection without interrupting a vacuum by using the reactive ion plasma etching chamber, the ion beam etching chamber, and the coating chamber in combination. The invention can effectively reduce damages and contaminations of devices, avoid the influence caused by over-etching, and improve performance of devices; at the same time, it can accurately control the steepness of an etching pattern and obtain a pattern result that meets performance requirements.

### TECHNICAL FIELD

The disclosure relates to the field of semiconductors, in particular to a method for manufacturing a magnetic tunnel junction.

### BACKGROUND OF THE INVENTION

The magnetic tunnel junction is the core structure of the magnetic random access memory, including a cap layer, a pinned layer, a non-magnetic isolation layer, and a free layer. Under the free layer, there may be a bottom electrode metal layer or a dielectric layer. The pinned layer is relatively thicker and has strong magnetism and its magnetic moment is not easy to reverse, while the free layer is relatively thinner and has weak magnetism and its magnetic moment is easy to reverse. The materials for the magnetic tunnel junction are materials that are difficult to be dry etched, such as Fe, Co, Mg, etc., for which it is difficult to form volatile products, and a corrosive gas such as Cl₂ cannot be used, otherwise it will affect the performance of the magnetic tunnel junction, so more complicated etching method is required for the etching, and the etching process is very difficult and challenging.

Reactive ion etching is commonly used in the etching of magnetic tunnel junctions. Reactive ion etching has the characteristics of high plasma density, thus even if it is difficult for the materials of the magnetic tunnel junction to form a volatilized product, it can realize rapid etching of the magnetic tunnel junction and obtain a suitable morphology due to the high plasma density. The etching process can achieve a higher etching speed with a lower physical bombardment force. However, reactive ion etching has some problems in the etching of magnetic tunnel junctions. The etching process of reactive ion etching includes chemical etching and physical etching. Chemical etching will cause chemical damage to a sidewall of a magnetic tunnel junction and affect magnetism of the magnetic tunnel junction and performance of device. In addition, the low physical bombardment etching during the etching process may cause secondary deposition on the sidewall and bottom of the magnetic tunnel junction, resulting in metal contaminations, especially when metal contaminations occur on the isolation layer, it will directly cause the insulating layer of the device to be conducted and results in loss of device function. As the size of magnetic tunnel junction devices becomes smaller and smaller, the impact of metal contaminations on the performance becomes more and more important. Avoiding metal contamination is very essential to realize highly integrated devices.

### SUMMARY OF THE INVENTION

In order to solve the above problems, embodiments of the present invention disclose a method for manufacturing a magnetic tunnel junction, using an etching apparatus including a sample loading chamber, a vacuum transition chamber, a reactive ion plasma etching chamber, an ion beam etching chamber, a coating chamber and a vacuum transmission chamber, wherein the vacuum transition chamber is respectively connected with the sample loading chamber and the vacuum transmission chamber in a communicable manner, the reactive ion plasma etching chamber, the ion beam etching chamber and the coating chamber are respectively connected with the vacuum transmission chamber in a communicable manner; the method being applicable for the reactive ion plasma etching chamber, the ion beam etching chamber and the coating chamber to treat and process a wafer without interrupting a vacuum; and the method comprising the following steps: a sample preparation step of forming on a semiconductor substrate a structure to be etched including a bottom electrode metal layer, a magnetic tunnel junction, a cap layer and a mask layer; a sample loading step of loading the sample into the sample loading chamber, and passing the sample through the vacuum transition chamber to the vacuum transmission chamber; an ion beam etching step of bringing the sample into the ion beam etching chamber, and etching the sample through an ion beam etching process until the bottom electrode metal layer is reached, and then returning the sample back to the vacuum transmission chamber; a reactive ion cleaning step of bringing the sample into the reactive ion plasma etching chamber to remove metal residues and perform surface treatment on the sample with reactive ion plasma so as to completely remove metal contaminations and a sidewall damage layer formed in the ion beam etching step, and then returning the sample back to the vacuum transmission chamber; a protection step of bringing the sample into the coating chamber to perform coating on the upper surface and the periphery of the sample after etching for protection, and then returning the sample back to the vacuum transmission chamber; and a sample taking step of returning the sample from the vacuum transmission chamber through the vacuum transition chamber to the sample loading chamber.

Another method for manufacturing a magnetic tunnel junction, using an etching apparatus including a sample loading chamber, a vacuum transition chamber, a reactive ion plasma etching chamber, an ion beam etching chamber, a coating chamber, and a vacuum transmission chamber, wherein the vacuum transition chamber is respectively connected with the sample loading chamber and the vacuum transmission chamber in a communicable manner, the reactive ion plasma etching chamber, the ion beam etching chamber, and the coating chamber are respectively connected with the vacuum transmission chamber in a communicable manner; the method being applicable for the reactive ion plasma etching chamber, the ion beam etching chamber, and the coating chamber to treat and process a wafer without interrupting a vacuum; and the method comprising the following steps: a sample preparation step of forming on the semiconductor substrate a structure to be etched including a bottom electrode metal layer, a magnetic tunnel junction, a cap layer and a mask layer, the magnetic tunnel junction including a pinned layer, an isolation layer and a free layer; a sample loading step of loading the sample into the sample loading chamber, and passing the sample through the vacuum transition chamber to the vacuum transmission chamber; an ion beam etching step of bringing the sample into the ion beam etching chamber and etching the sample through an ion beam etching process until a position in the pinned layer close to the bottom electrode metal layer is reached, and then returning the sample back to the vacuum transmission chamber; an ion beam cleaning step of maintaining the sample in the ion beam etching chamber and removing metal residues and performing sample surface treatment with ion beams to completely remove metal contaminations and a sidewall damage layer formed in the ion beam etching step, and then returning the sample back to the vacuum transmission chamber; a dielectric coating step of bringing the sample into the coating chamber and forming a dielectric film on the upper surface and the periphery of the sample, and then returning the sample back to the vacuum transmission chamber; a reactive ion etching step of bringing the sample into the reactive ion plasma etching chamber, and removing the dielectric film on the top and bottom of the device and retaining a part of the dielectric film at the sidewall of the device, and performing the etching until the bottom electrode metal layer is reached, then returning the sample back to the vacuum transmission chamber; a protection step of bringing the sample into the coating chamber, and performing coating on the upper surface and periphery of the sample after etching for protection, and then returning the sample back to the vacuum transmission chamber; and a sample taking step of returning the sample from the vacuum transmission chamber through the vacuum transition chamber to the sample loading chamber.

In the method for manufacturing a magnetic tunnel junction of the present invention, optionally, the magnetic tunnel junction has a structure where the pinned layer is above the isolation layer or the pinned layer is below the isolation layer.

In the method for manufacturing a magnetic tunnel junction of the present invention, optionally, the isolation layer of the magnetic tunnel junction is a single layer or multiple layers.

In the method for manufacturing a magnetic tunnel junction of the present invention, optionally, in the ion beam etching step, a gas used includes inert gas, nitrogen, oxygen, or any combinations thereof.

In the method for manufacturing a magnetic tunnel junction of the present invention, optionally, in the reactive ion plasma etching chamber, a gas used includes inert gas, nitrogen, oxygen, fluorine-based gas, NH₃, amino gas, CO, CO₂, alcohols or any combinations thereof.

In the method for manufacturing a magnetic tunnel junction of the present invention, optionally, the dielectric film is Group IV oxides, Group IV nitrides, Group IV oxynitrides, transition metal oxides, transition metal nitrides, and transition metal oxynitrides, alkaline earth metal oxides, alkaline earth metal nitrides, alkaline earth metal oxynitrides or any combinations thereof.

In the method for manufacturing a magnetic tunnel junction of the present invention, preferably, in the protection step, a thickness of the film coated is 1 nm to 500 nm.

In the method for manufacturing a magnetic tunnel junction of the present invention, preferably, in the reactive ion cleaning step, the sidewall of the magnetic tunnel junction is removed by a thickness of 0.1 nm to 5.0 nm.

In the method for manufacturing a magnetic tunnel junction of the present invention, preferably, in the dielectric coating step, a thickness of the dielectric film coated is 0.5 nm-50 nm.

### BRIEF DESCRIPTION OF THE DRAWINGS

FIG. 1 is a functional block diagram of an etching apparatus used in a magnetic tunnel junction etching method of the present invention.

FIG. 2 is a schematic diagram of a structure to be etched including a magnetic tunnel junction with a pinned layer being below an isolation layer.

FIG. 3 is a schematic diagram of a structure to be etched including a magnetic tunnel junction with a pinned layer being above the isolation layer.

FIG. 4 is a flowchart of an embodiment of a method for manufacturing a magnetic tunnel junction.

FIG. 5 is a schematic diagram of a device structure formed after an ion beam etching step.

FIG. 6 is a schematic diagram of a device structure formed after a reactive ion cleaning step.

FIG. 7 is a schematic diagram of a device structure formed after a protection step.

FIG. 8 is a flowchart of another embodiment of a method for manufacturing a magnetic tunnel junction.

FIG. 9 is a schematic diagram of a device structure formed when an ion beam etching is stopped in the pinned layer and a cleaning is completed.

FIG. 10 is a schematic diagram of a device structure formed after a dielectric coating step.

FIG. 11 is a schematic diagram of a device structure formed after a reactive ion etching reaches a bottom electrode metal layer.

FIG. 12 is a schematic diagram of a device structure formed after a protection step.

### DETAILED DESCRIPTION OF THE INVENTION

In order to make the objectives, technical solutions, and advantages of the present invention clearer, the technical solutions in the embodiments of the present invention will be clearly and completely described in the following with reference to the accompanying drawings in the embodiments of the present invention. It should be understood that the specific embodiments described herein are only used to explain the present invention, but not used to limit the present invention. The described embodiments are only parts of embodiments of the present invention, rather than all embodiments. Based on the embodiments of the present invention, all other embodiments obtained by those of ordinary skill in the art without creative work shall fall within the protection scope of the present invention.

In the description of the present invention, it should be noted that the orientations or positional relationships indicated by the terms “upper”, “lower”, “vertical”, “horizontal”, etc. are based on the orientations or positional relationships shown in the drawings, and are only for convenience of describing the present invention and simplifying the description, rather than indicating or implying that the apparatus or element referred to must have a specific orientation, be constructed and operated in a specific orientation, and therefore cannot be understood as a limitation of the present invention. In addition, the terms “first” and “second” are only used for descriptive purposes, and cannot be understood as indicating or implying relative importance.

In addition, many specific details of the present invention are described below, such as the structure, materials, dimensions, processing technology of a device, in order to understand the present invention more clearly. However, as those skilled in the art can understand, the present invention may not be implemented according to these specific details. Unless specifically indicated in the following, each part of the device may be composed of materials known to those skilled in the art, or be made from materials with similar functions developed in the future.

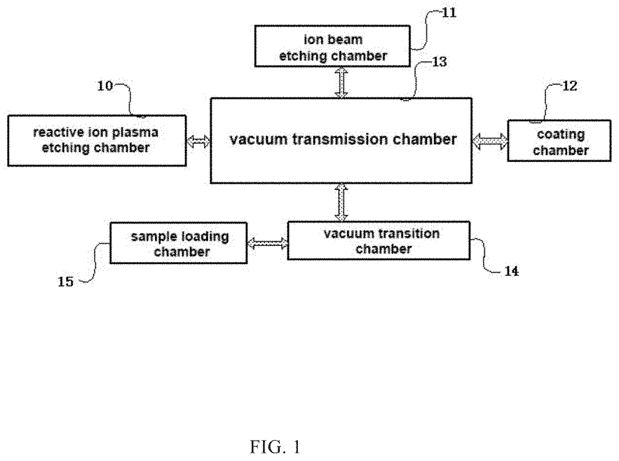

An apparatus used in a method for manufacturing a magnetic tunnel junction of the present invention will be described below with reference to accompanying drawings. FIG. 1 is a functional block diagram of an etching apparatus used in the method for manufacturing a magnetic tunnel junction of the present invention. As shown in FIG. 1, the etching apparatus includes a reactive ion plasma etching chamber 10, an ion beam etching (IBE) chamber 11, a coating chamber 12, a vacuum transmission chamber 13, a vacuum transition chamber 14 and a sample loading chamber 15. The vacuum transition chamber 14 is respectively connected with the sample loading chamber 15 and the vacuum transmission chamber 13 in a communicable manner. The reactive ion plasma etching chamber 10, the ion beam etching chamber 11, and the coating chamber 12 are respectively connected with the vacuum transmission chamber 13 in a communicable manner. In addition, there may be a plurality of each of the above-mentioned chambers.

The reactive ion plasma etching chamber 10 may be a reactive ion plasma etching chamber such as an inductively coupled plasma (ICP) chamber, a capacitively coupled plasma (CCP) chamber, or a spiral wave plasma chamber. The ion beam etching (IBE) chamber 11 may be an ion beam etching chamber, a neutral particle beam etching chamber, or the like. The coating chamber 12 can be a physical vapor deposition (PVD) coating chamber, or a chemical vapor deposition (CVD) coating chambers such as a pulsed chemical vapor deposition (Pulsed CVD) coating chamber, a plasma enhanced chemical vapor deposition (PECVD) coating chamber, an inductively coupled plasma enhanced chemical vapor deposition (ICP-PECVD) coating chamber and atomic layer (ALD) coating chamber.

In addition, the etching apparatus may also include functional units that are included in a conventional etching apparatus and are, e.g., a sample transmission system for realizing the transfer of samples in different chambers, a control system for controlling each chamber and the sample transfer system, etc., a vacuum pumping system for achieving a vacuum degree required for each chamber and a cooling system. These apparatus structures can be implemented by those skilled in the art using existing technology.

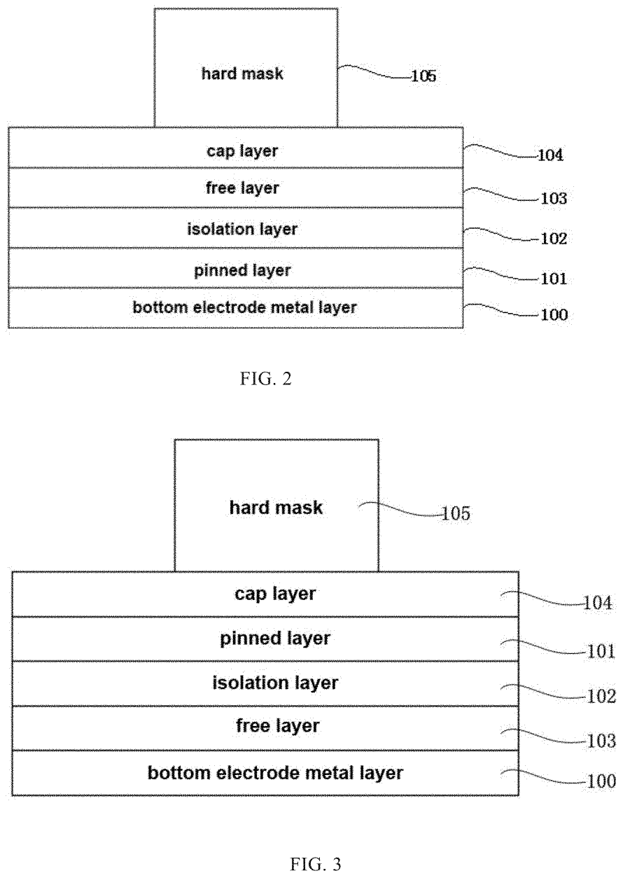

FIG. 2 shows a schematic diagram of a structure of a device to be etched including a magnetic tunnel junction. As shown in FIG. 2, the structure to be etched includes a bottom electrode metal layer 100, a magnetic tunnel junction (including a pinned layer 101, an isolation layer 102 and a free layer 103), a cap layer 104 and a hard mask layer 105. It should be noted that this structure is only an example. In actual applications, the constitution of the magnetic tunnel junction can also be that, the free layer is below the isolation layer and the pinned layer is above the isolation layer, as shown in FIG. 3. In addition, the isolation layer can also be two or more layers, and so on. The method for manufacturing a magnetic tunnel junction of the present invention is applicable to all these different structures.

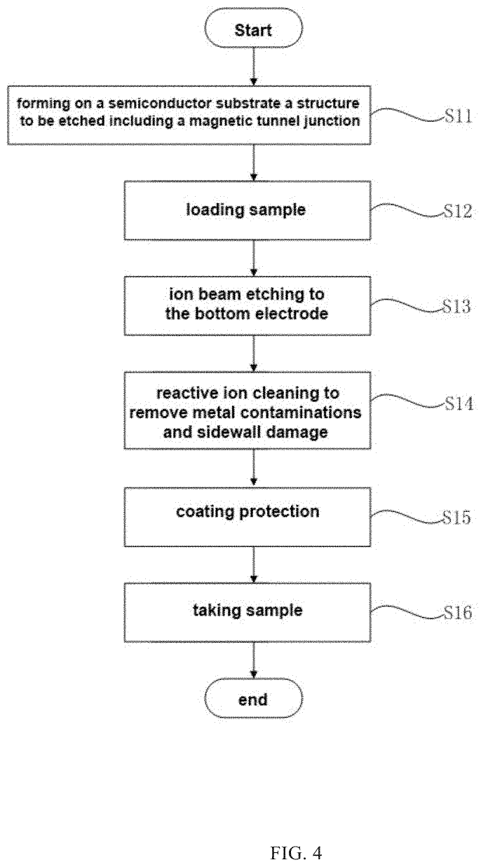

In the following, the structure to be etched shown in FIG. 2 is taken as an example to explain a method for manufacturing a magnetic tunnel junction of the present invention in detail. FIG. 4 is a flow chart of an embodiment of a method for manufacturing a magnetic tunnel junction of the present invention.

First, in a sample preparation step S11, a structure to be etched including a magnetic tunnel junction is formed on the semiconductor substrate. The specific structure is shown in FIG. 2.

Next, in the sample loading step S12, the sample is loaded into the sample loading chamber 15, and brought into the vacuum transmission chamber 13 through the vacuum transition chamber 14.

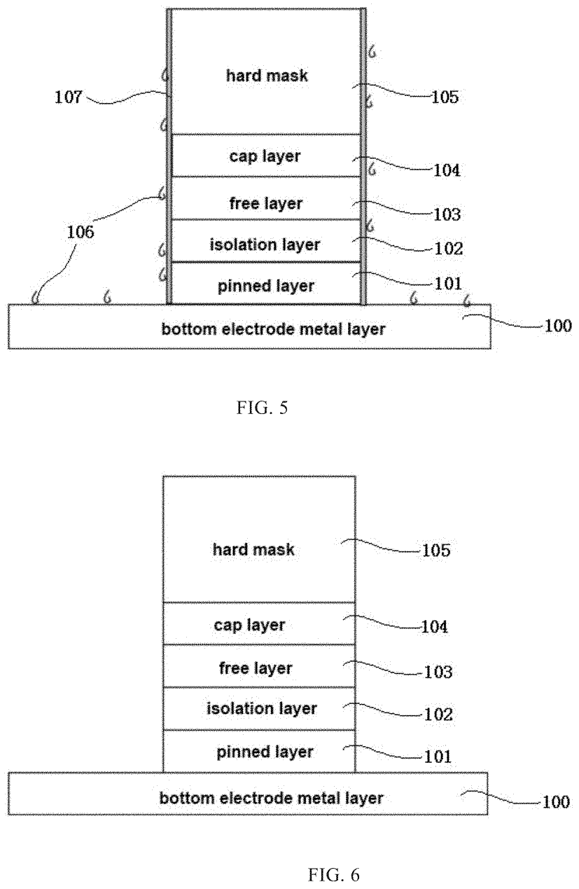

Next, in an ion beam etching step S13, the sample is brought into the ion beam etching chamber 11 where the sample is completely etched through an ion beam etching process, and then the sample is returned back to the vacuum transmission chamber 13. A gas used in the ion beam etching can be inert gas, nitrogen, oxygen, and the like. An angle used in the ion beam etching is 10 degrees to 80 degrees, which refers to an angle between an ion beam and a normal direction of a wafer surface. When the etching reaches the bottom electrode metal layer, the etching is stopped, Typically, optical or secondary ion mass spectrometry is used to monitor an etching end point. The etching process must realize separation of devices and a required steepness of the devices. No metal contamination is a target for a sidewall of the device formed by etching; however nano-scale metal contaminations, or a very small amount of metal contaminations, such as less than 1 nm, are difficult to completely avoid. At the same time, a nano-scale damage layer on the sidewall of the magnetic tunnel junction may be produced during the etching process, and metal residues above the bottom electrode metal layer of the device and above a dielectric layer between the bottom electrode metal layers of different devices may not be completely removed. FIG. 5 is a schematic diagram of a device structure formed after the ion beam etching step. FIG. 5 schematically shows metal contaminations 106 and a damage layer 107 on the sidewall of the magnetic tunnel junction formed during the ion beam etching process.

Next, in a reactive ion cleaning step 814, the sample is brought into the reactive ion etching chamber 10 to remove metal residues and perform sample surface treatment through a reactive ion etching process, so as to remove the sidewall of the magnetic tunnel junction by a thickness of 0.1 nm˜5.0 nm, to completely remove the sidewall metal contaminations and the sidewall damage layer formed in the ion beam etching step S13, and at the same time, to completely remove the metal residues above the bottom electrode metal layer of the devices and above the dielectric layers between the bottom electrode metal layers of different devices, so as to realize complete electrical isolation between the devices and avoid short circuit between the device and the device. The sample is then returned back to the vacuum transmission chamber 13. A gas used in the reactive ion etching can be inert gas, nitrogen, oxygen, fluorine-based gas, NH₃, amino gas, CO, CO₂, alcohols, etc. After the device undergoes the above-mentioned etching steps in two chambers, the sidewalls of the devices are clean and the devices are completely separated. FIG. 6 shows a schematic diagram of a device structure formed after the reactive ion cleaning step.

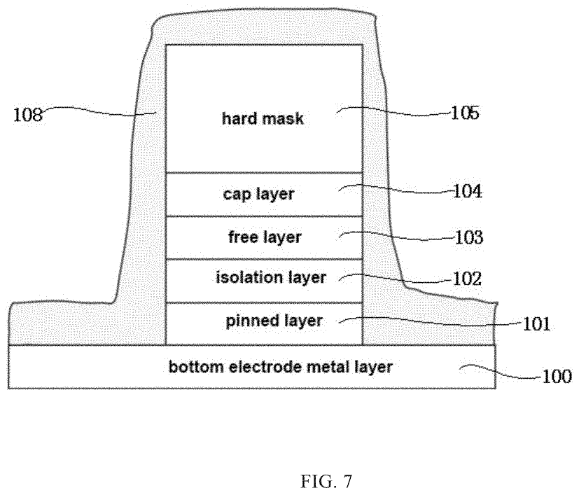

Next, in the protection step S15, the sample is brought into the coating chamber 12, and a coating for protection is performed on the upper surface and the periphery of the sample after etching, and then the sample is returned back to the vacuum transmission chamber 13. FIG. 7 shows a schematic diagram of a device structure formed after the protection step. In the figure, a coating film 108 is a dielectric material that separates adjacent magnetic tunnel junction devices. The dielectric film material may be dielectric material capable of separating adjacent magnetic tunnel junction devices, such as Group IV oxides, Group IV nitrides, Group IV oxynitrides, transition metal oxides, transition nitrides, transition oxynitrides, alkaline earth metal oxides, alkaline earth nitrides, and alkaline earth oxynitrides. A thickness of the coating film can be 1 nm˜500 nm. The in-situ coating protection in the coating chamber can prevent the device from being damaged by being exposed to the atmosphere in the subsequent process, and at the same time realize complete insulation and isolation between devices.

Finally, in a sample taking step S16, the sample is returned from the vacuum transmission chamber 13 to the sample loading chamber 15 through the vacuum transition chamber 14.

The method for manufacturing a magnetic tunnel junction of the present invention uses an ion beam etching chamber to pattern a magnetic tunnel junction, which can precisely control the steepness of an etching pattern, and as a result, obtain a pattern that meets performance requirements. Under the premise of not breaking a vacuum, a reactive ion plasma etching chamber is used to perform surface treatment on the magnetic tunnel junction so as to remove adverse effects brought by an ion beam etching process, such as device damage and contamination, and improve device performance. The manufacturing process for manufacturing a magnetic tunnel junction according to the present invention is always maintained in a vacuum environment, which avoids the influence of external environment on the etching.

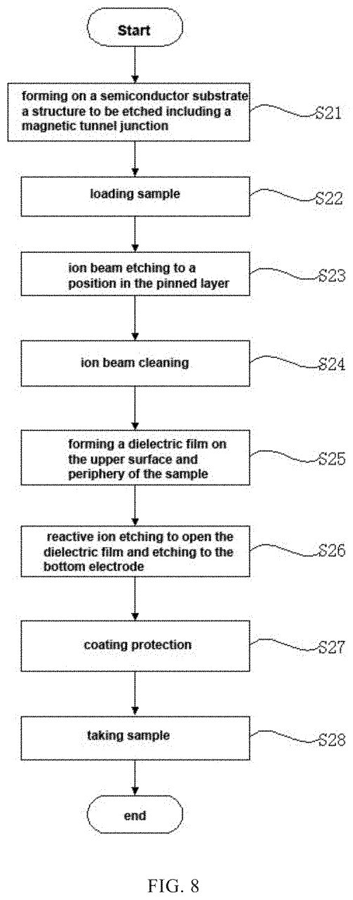

FIG. 8 is a flowchart of another embodiment of a method for manufacturing a magnetic tunnel junction. As shown in FIG. 8, first, in a sample preparation step S21, a structure to be etched including a magnetic tunnel junction is formed on a semiconductor substrate. The specific structure is shown in FIG.

Next, in a sample loading step 822, the sample is loaded into the sample loading chamber 15, and then the sample is passed through the vacuum transition chamber 14 into the vacuum transmission chamber 13.

Next, in an ion beam etching step S23, the sample is brought into an ion beam etching chamber 11, where the sample is etched by an ion beam etching process. When the etching reaches a position in the pinned layer close to the bottom electrode metal layer, the etching is stopped, leaving only a pinned layer of a few nanometers thick, and then the sample is returned back to the vacuum transmission chamber 13. A gas used in the ion beam etching can be inert gas, nitrogen, oxygen, and the like. An angle used in the ion beam etching is 10 degrees to 80 degrees, which refers to an angle between an ion beam and a normal direction of a wafer surface.

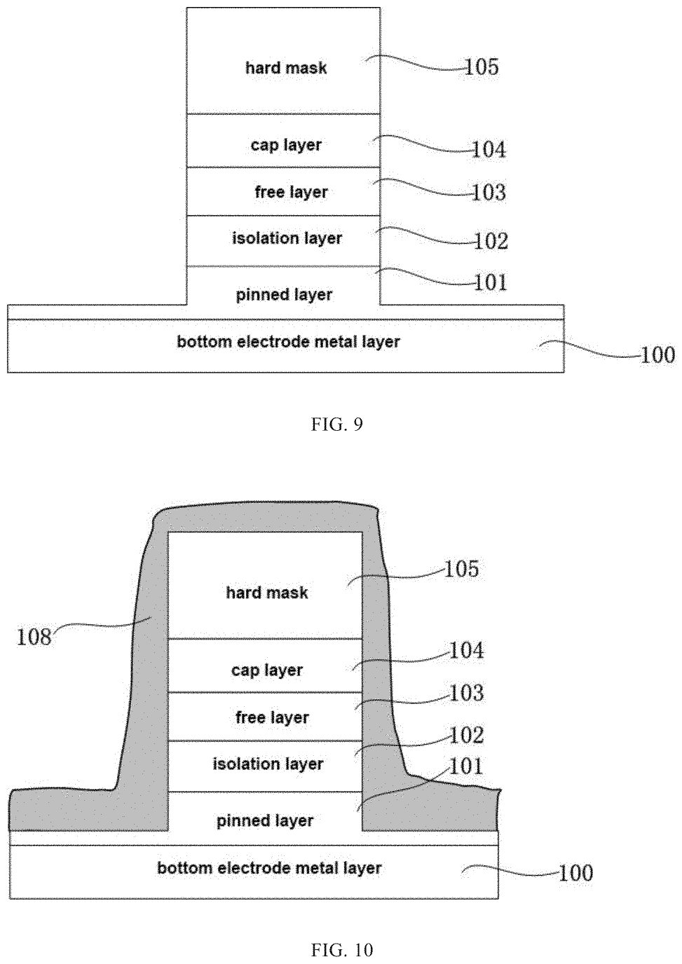

Next, in an ion beam cleaning step S24, the sample is maintained in the ion beam etching chamber 11 to be cleaned by ion beams. Through further ion beam cleaning, the metal contaminations and sidewall damage formed during the ion beam etching process can be removed. The resulting structure is shown in FIG. 9. Then the sample is returned back to the vacuum transmission chamber 13. A gas used in the ion beam cleaning can be inert gas, nitrogen, oxygen, etc., and an angle used is preferably 10 degrees to 80 degrees. The gas and angle used in this step may be the same as or different from the gas and angle used in the ion beam etching step.

In a dielectric coating step S25, the sample is brought into the coating chamber 12, and a dielectric film 108 is formed on the upper surface and the periphery of the sample. A structure obtained is shown in FIG. 10, and then the sample is returned back to the vacuum transmission chamber 13. The material of the dielectric film can be Group IV oxides, Group IV nitrides, Group IV oxynitrides, transition metal oxides, transition metal nitrides, transition metal oxynitrides, alkaline earth metal oxides, alkaline earth metal nitrides, alkaline earth metal oxynitrides and other dielectric materials that can realize separation of adjacent magnetic tunnel junction devices. A thickness of the dielectric coating film can be 0.5 nm˜50 nm.

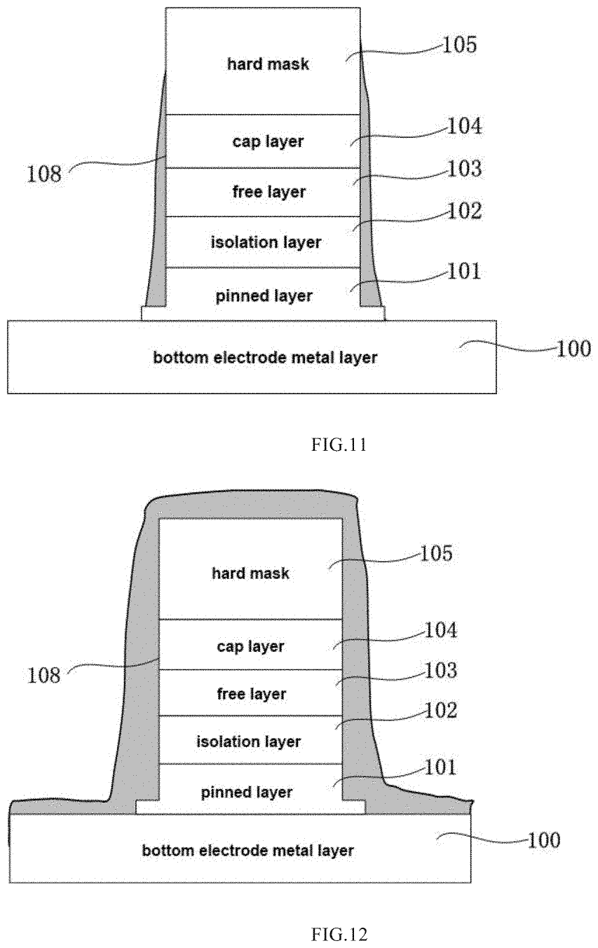

In a reactive ion etching step 826, the sample is brought into the reactive ion etching chamber 10 to be etched by reactive ion plasma, so that the dielectric films on the top and bottom of the device are opened (removed) and a part of the dielectric film on the sidewall of the device is retained. When the bottom electrode metal layer 100 is reached, the etching is stopped; then the sample is returned back to the vacuum transmission chamber 13. A gas used in the reactive ion etching can be inert gas, nitrogen, oxygen, fluorine-based gas, NH₃, amino gas, CO, CO₂, alcohols, etc. FIG. 11 shows a schematic diagram of a device structure formed after the reactive ion etching step. In this step, by adjusting the selection of process gases, a high selection ratio can be achieved, over-etching can be effectively reduced, and device yield can be improved.

Next, in a protection step S27, the sample is brought into the coating chamber 12, where a dielectric film 108 is formed on the upper surface and the periphery of the sample after the etching, and then the sample is returned back to the vacuum transmission chamber 13. FIG. 12 shows a schematic diagram of a device structure after the protection step. In the figure, the dielectric film 108 is a dielectric material that separates adjacent magnetic tunnel junction devices, such as group IV oxides, group IV nitrides, group IV oxynitrides, transition metal oxides, transition nitrides, transition oxynitrides, alkaline earth metal oxides, alkaline earth nitrides, alkaline earth oxynitrides, etc. A thickness of the dielectric film can be 1 nm to 500 nm. The in-situ coating protection in the coating chamber can prevent the device from being damaged by being exposed to the atmosphere in the subsequent process, and at the same time realize complete insulation and isolation between devices.

Finally, in a sample taking step S28, the sample is returned from the vacuum transmission chamber 13 through the vacuum transition chamber 14 to the sample loading chamber 15.

This embodiment is described for a magnetic tunnel junction in which the pinned layer is below the isolation layer and the free layer is above the isolation layer. For a magnetic tunnel junction where the pinned layer is above the isolation layer and the free layer is below the isolation layer, in the ion beam etching step S23, correspondingly, the etching is stopped at a position in the free layer close to the bottom electrode metal layer.

The specific embodiments of a method for manufacturing a magnetic tunnel junction of the present invention have been described in detail above, but the present invention is not limited to thereto. The specific implementation of each step can be different according to the situation. In addition, the order of some steps can be exchanged, and some steps can be omitted. The etching or cleaning step in the reactive ion plasma chamber can be a single step or multiple steps. In the case of multiple steps, the gases, power, gas flow, and pressure used in different steps can be the same or different. The etching or cleaning step in the ion beam etching chamber can be a single step or multiple steps. In the case of multiple steps, the gases, the angles of the sample stage relative to the ion beam, the energy and density of the ion beams can be the same or different in different steps. In addition, the method for manufacturing a magnetic tunnel junction of the present invention is applicable to the etching of magnetic tunnel junctions, transition metals and their oxides. The method for manufacturing a magnetic tunnel junction of the present invention is applicable to the etching of magnetic tunnel junctions with a pinned layer above an isolation layer or a pinned layer below an isolation layer. The method for manufacturing a magnetic tunnel junction of the present invention is applicable to the etching of magnetic tunnel junctions with an isolation layer of a single layer or multiple layers.

The above are only specific embodiments of the present invention, but the scope of protection of the present invention is not limited thereto. Any changes or substitutions occurred to those skilled in the art within the technical scope disclosed by the present invention should all be covered within the protection scope of the present invention.

1. A method for manufacturing a magnetic tunnel junction, using an etching apparatus including a sample loading chamber, a vacuum transition chamber, a reactive ion plasma etching chamber, an ion beam etching chamber, a coating chamber and a vacuum transmission chamber, wherein the vacuum transition chamber is respectively connected with the sample loading chamber and the vacuum transmission chamber in a communicable manner, and the reactive ion plasma etching chamber, the ion beam etching chamber and the coating chamber are respectively connected with the vacuum transmission chamber in a communicable manner; the method being applicable for the reactive ion plasma etching chamber, the ion beam etching chamber and the coating chamber to treat and process a wafer without interrupting a vacuum; and the method comprising the following steps:
a sample preparation step of forming on a semiconductor substrate a structure to be etched including a bottom electrode metal layer, a magnetic tunnel junction, a cap layer and a mask layer;
a sample loading step of loading the sample into the sample loading chamber and passing the sample through the vacuum transition chamber into the vacuum transmission chamber;
an ion beam etching step of bringing the sample into the ion beam etching chamber and etching the sample through an ion beam etching process until the bottom electrode metal layer is reached, and then returning the sample back to the vacuum transmission chamber;
a reactive ion cleaning step of bringing the sample into the reactive ion plasma etching chamber to remove metal residues and perform sample surface treatment with reactive ion plasma so as to completely remove metal contaminations and a sidewall damage layer formed in the ion beam etching step, and then returning the sample back to the vacuum transmission chamber;
a protection step of bringing the sample into the coating chamber to perform coating on the upper surface and the periphery of the sample after etching for protection, and then returning the sample back to the vacuum transmission chamber; and
a sample taking step of returning the sample from the vacuum transmission chamber through the vacuum transition chamber to the sample loading chamber.

2. (canceled)

3. The method for manufacturing a magnetic tunnel junction according to claim 1, wherein:
the magnetic tunnel junction has a structure where the pinned layer is above the isolation layer or the pinned layer is below the isolation layer.

4. The method for manufacturing a magnetic tunnel junction according to claim 1, wherein:
the isolation layer of the magnetic tunnel junction comprises a single layer or multiple layers.

5. The method for manufacturing a magnetic tunnel junction according to claim 1, wherein:
in the ion beam etching step, a gas used comprises inert gas, nitrogen, oxygen, or any combinations thereof.

6. The method for manufacturing a magnetic tunnel junction according to claim 1, wherein:
in the reactive ion plasma etching chamber, a gas used comprises inert gas, nitrogen, oxygen, fluorine-based gas, NH₃, amino gas, CO, CO₂, alcohols or any combinations thereof.

7. The method for manufacturing a magnetic tunnel junction according to claim 1, wherein:
the dielectric film is Group IV oxides, Group IV nitrides, Group IV oxynitrides, transition metal oxides, transition metal nitrides, and transition metal oxynitrides, alkaline earth metal oxides, alkaline earth metal nitrides, alkaline earth metal oxynitrides, or any combinations thereof.

8. The method for manufacturing a magnetic tunnel junction according to claim 1, wherein:
in the protection step, a thickness of the dielectric film coated is 1 nm to 500 nm.

9. The method for manufacturing a magnetic tunnel junction according to claim 1, wherein:
in the reactive ion cleaning step, the sidewall of the magnetic tunnel junction is removed by a thickness of 0.1 nm to 5.0 nm.

10. (canceled)

11. A method for manufacturing a magnetic tunnel junction, using an etching apparatus including a sample loading chamber, a vacuum transition chamber, a reactive ion plasma etching chamber, an ion beam etching chamber, a coating chamber, and a vacuum transmission chamber, wherein the vacuum transition chamber is respectively connected with the sample loading chamber and the vacuum transmission chamber in a communicable manner, and the reactive ion plasma etching chamber, the ion beam etching chamber, and the coating chamber are respectively connected with the vacuum transmission chamber in a communicable manner; the method being applicable for the reactive ion plasma etching chamber, the ion beam etching chamber, and the coating chamber to treat and process a wafer without interrupting a vacuum; and the method comprising the following steps:
a sample preparation step of forming on a semiconductor substrate a structure to be etched including a bottom electrode metal layer, a magnetic tunnel junction, a cap layer and a mask layer, the magnetic tunnel junction including a pinned layer, an isolation layer and a free layer;
a sample loading step of loading the sample into the sample loading chamber, and passing the sample through the vacuum transition chamber to the vacuum transmission chamber;
an ion beam etching step of bringing the sample into the ion beam etching chamber and etching the sample through an ion beam etching process until a position in the pinned layer close to the bottom electrode metal layer is reached, and then returning the sample back to the vacuum transmission chamber;
an ion beam cleaning step of maintaining the sample in the ion beam etching chamber and removing metal residues and performing sample surface treatment with ion beams to completely remove metal contaminations and a sidewall damage layer formed in the ion beam etching step, and then returning the sample back to the vacuum transmission chamber;
a dielectric coating step of bringing the sample into the coating chamber and forming a dielectric film on the upper surface and the periphery of the sample, and then returning the sample back to the vacuum transmission chamber;
a reactive ion etching step of bringing the sample into the reactive ion plasma etching chamber, and removing the dielectric film on the top and bottom of the device and retaining a part of the dielectric film at the sidewall of the device, and performing the etching until the bottom electrode metal layer is reached, then returning the sample back to the vacuum transmission chamber;
a protection step of bringing the sample into the coating chamber, and performing coating on the upper surface and periphery of a etched sample for protection, and then returning the sample back to the vacuum transmission chamber; and
a sample taking step of returning the sample from the vacuum transmission chamber through the vacuum transition chamber to the sample loading chamber.

12. The method for manufacturing a magnetic tunnel junction according to claim 11, wherein:
the isolation layer of the magnetic tunnel junction comprises a single layer or multiple layers.

13. The method for manufacturing a magnetic tunnel junction according to claim 11, wherein:
in the ion beam etching step, a gas used comprises inert gas, nitrogen, oxygen, or any, combinations thereof.

14. The method for manufacturing a magnetic tunnel junction according to claim 11, wherein:
in the reactive ion plasma etching chamber, a gas used comprises inert gas, nitrogen, oxygen, fluorine-based gas, NH₃, amino gas, CO, CO₂, alcohols or any combinations thereof.

15. The method for manufacturing a magnetic tunnel junction according to claim 11, wherein:
the dielectric film is Group IV oxides, Group IV nitrides, Group IV oxynitrides, transition metal oxides, transition metal nitrides, and transition metal oxynitrides, alkaline earth metal oxides, alkaline earth metal nitrides, alkaline earth metal oxynitrides, or any combinations thereof.

16. The method for manufacturing a magnetic tunnel junction according to claim 11, wherein:
in the protection step, a thickness of the dielectric film coated is 1 nm to 500 nm.

17. The method for manufacturing a magnetic tunnel junction according to claim 11, wherein:
in the dielectric coating step, a thickness of the dielectric film coated is 0.5 nm-50 nm.
